(19) United States
(12) Patent Application Publication
(10) Pub. No.: US 2025/0004363 A1
(43) Pub. Date: Jan. 2, 2025

(54) ZIRCONIUM-COATED ULTRA-THIN, ULTRA-LOW DENSITY FILMS FOR EUV LITHOGRAPHY

(71) Applicant: LINTEC OF AMERICA, INC., Plano, TX (US)

(72) Inventors: Marcio D. LIMA, Richardson, TX (US); Mary Viola GRAHAM, Richardson, TX (US); Takahiro UEDA, Frisco, TX (US)

(73) Assignee: LINTEC OF AMERICA, INC., Plano, TX (US)

(21) Appl. No.: 18/695,930

(22) PCT Filed: Sep. 27, 2022
(86) PCT No.: PCT/US2022/044878

§ 371 Date: Mar. 27, 2024

Related U.S. Application Data
(60) Provisional application No. 63/312,658, filed on Feb. 22, 2022.
(60) Provisional application No. 63/249,118, filed on Sep. 28, 2021.

(51) Int. Cl. G03F 1/64; B82Y 30/00

(52) U.S. Cl. CPC G03F 1/64; B82Y 30/00

(57) ABSTRACT

A filtration formed nanostructure pellicle film with an ultra-thin zirconium coating is disclosed. The filtration formed nanostructure pellicle film includes a plurality of nanotubes that are intersected randomly to form an interconnected network structure in a planar orientation with enhanced properties, and a zirconium-coated layer. The coated interconnected structure with the zirconium-coated layer allows for a high minimum EUV transmission rate of at least 88%. The interconnected network structure has a thickness ranging from a lower limit of 3 nm to an upper limit of 100 nm, to allow for effective EUV lithography processing.

### CROSS-REFERENCE TO RELATED APPLICATION

This application claims priority to U.S. Provisional Patent Application No. 63/249,118, filed Sep. 28, 2021 and U.S. Provisional Patent Application No. 63/312,658, filed Feb. 22, 2022. The disclosure of each of these documents, including the specification, drawings, and claims, is incorporated herein by reference in its entirety.

### TECHNICAL FIELD

This disclosure generally relates to a thin film and thin film device used in a semiconductor microchip fabrication and, more particularly, to an ultra-thin, ultra-low density, zirconium-coated nanostructured free-standing pellicle film and device for extreme ultraviolet (EUV) photolithography.

### BACKGROUND

A pellicle is a protective device that covers a photomask and is used in semiconductor microchip fabrication. The photomask may refer to an opaque plate with holes or transparencies that allow light to shine through in a defined pattern. Such photomasks may be commonly used in photolithography and the production of integrated circuits. As a master template, the photomask is used to produce a pattern on a substrate, normally a thin slice of silicon known as a wafer in the case of semiconductor chip manufacturing.

Particle contamination can be a significant problem in semiconductor manufacturing. A photomask is protected from particles by a pellicle, which has a thin transparent film stretched over a pellicle frame that is attached over the patterned side of the photomask. The pellicle is close but far enough away from the mask so that moderate-to-small-sized particles that land on the pellicle will be too far out of focus to print. Recently, the microchip manufacturing industry realized that the pellicle might also protect the photomask from damage stemming from causes other than particles and contaminants.

Extreme ultraviolet photolithography is an advanced optical lithography technology using a range of EUV wavelengths, more specifically, a 13.5 nm wavelength. It enables semiconductor microchip manufacturers to pattern the most sophisticated features at 7 nm resolution and beyond and put many more transistors without increasing the size of the required space. EUV photomasks work by reflecting light, which is achieved by using multiple alternating layers of molybdenum and silicon. When an EUV light source turns on, the EUV light hits the pellicle film first, passes through the pellicle film, and then bounces back from underneath the photomask, hitting the pellicle film once more before it continues its path to print a microchip. Some of the energy is absorbed during this process, and heat may be generated, absorbed, and accumulated as a result. The temperature of the pellicle may heat up to anywhere from 450 to 1000° Celsius or above.

While heat resistance is important, the pellicle must also be highly transparent for EUV light to ensure the passing through of the reflected light and light pattern from the photomask and have a low EUV scattering for printing accuracy and acuity for high production yield.

In 2016, a polysilicon-based EUV pellicle was developed after decades of research and effort with only 78% EUV transmission on a simulated relatively low-power 175-watt EUV light source. Due to greater transistor density demand, stringent requirements present further technical challenges to EUV pellicle developers for a higher transmission rate, lower transmission variation, higher temperature tolerance, and low light scattering.

Although attempts have been made to target a higher light transmittance rate by deploying a high single-walled carbon nanotube content in a carbon nanotube sheet (e.g., as high as 98% by mass), such attempts have resulted in a product that has inferior structure and a low lifetime. Accordingly, such carbon nanotube-based thin film has to provide a certain level of high-temperature tolerance under EUV irradiation for a certain period of time and little light scattering. As a result, EUV transmittance of such carbon nanotube-based thin film with a satisfactory product lifetime still did not meet the industry standard.

Furthermore, the heat generated during the photolithography process raises the temperate of the pellicle film from around 450° C. up to 1,000° C. or above, which shortens the lifetime of the pellicle film and eventually breaks it. Any broken pellicle film or pieces of the broken pellicle film may cause damages, contaminations, or adhesion of broken pellicle film to the scanner chamber and the underlining reticle and/or mask. When a pellicle film is weakened, the scanner may be required to vent the chamber, which in turn increases the risk of damaging the already weakened pellicle film. Accordingly, in such a situation, the scanner will be required to shut down and stop production, leading to lengthy downtimes.

In addition to the lifetime requirement, pellicle films must have very little light scattering. Any scattering may reduce image contrast of EUV optics affecting image reconstruction and EUV photolithography throughput.

Therefore, in conventional technology, achieving a high transmittance of EUV light, an excellent pellicle film lifetime, and low light scattering present new challenges in the field.

### SUMMARY

According to an aspect of the present disclosure, a specifically structured nanotube film is disclosed. The nanotube film includes a plurality of carbon nanotubes that are intersected randomly to form an interconnected network structure in a planar orientation with a thin layer of zirconium coating. The interconnected network structure has a thickness ranging from a lower limit of 3 nm to an upper limit of 100 nm and a minimum EUV transmission rate of 88% or above.

According to another aspect of the present disclosure, in some embodiments, a thickness ranges between the lower limit of 3 nm to an upper limit of 40 nm.

According to another aspect of the present disclosure, in some embodiments, a thickness ranges between the lower limit of 3 nm to an upper limit of 20 nm.

According to yet another aspect of the present disclosure, in some embodiments, the average thickness of the interconnected network structure is 11 nm.

According to a further aspect of the present disclosure, in some embodiments, an EUV transmission rate rises to above 92%.

According to a further aspect of the present disclosure, in some embodiments, an EUV transmission rate rises to above 95%.

According to yet another aspect of the present disclosure, in some embodiments, an EUV transmission rate rises to above 98%.

According to one aspect of the present disclosure, in some embodiments, a light transmission rate at 550 nm rises to around 80% or above.

According to another aspect of the present disclosure, in some embodiments, a light transmission rate at 550 nm rises to 90% or above.

According to a further aspect of the present disclosure, in some embodiments, a light transmission rate at 550 nm rises to 92.5% or above.

According to a further aspect of the present disclosure, the plurality of nanotubes further includes single-walled carbon nanotubes and multi-walled carbon nanotubes, and a number of walls of single-walled carbon nanotubes is one, a number of walls of the double-walled carbon nanotubes is two, and a number of walls of the multi-walled carbon nanotubes is three or more.

According to another aspect of the present disclosure, the single-walled carbon nanotubes account for a percentage between 20-40% of all carbon nanotubes, double-walled carbon nanotubes account for a percentage of 50% or higher of all carbon nanotubes, the remaining carbon nanotubes are multi-walled carbon nanotubes.

According to a further aspect of the present disclosure, the nanotube film further contains a zirconium-coated layer.

According to another aspect of the present disclosure, the average thickness of a zirconium-coated layer is 1.5 nm or less on one side of the nanotube film.

According to another aspect of the present disclosure, the average thickness of a zirconium-coated layer is 1 nm thick or less on each side of the nanotube film.

According to another aspect of the present disclosure, the average thickness of a zirconium-coated layer is 0.5 nm or less on each side of the nanotube film.

According to another aspect of the present disclosure, the average thickness of a zirconium-coated layer is about 0.3 nm thick on each side of the nanotube film.

According to one aspect of the present disclosure, the zirconium-coated layer covers both sides of the nanotube film.

According to another aspect of the present disclosure, the zirconium-coated layer covers one side of the nanotube film.

According to another aspect of the present disclosure, the zirconium-coated nanotube film has a scattering of 0.5% or less measured at the 4.7° (degree) angle.

According to another aspect of the present disclosure, the zirconium-coated nanotube film has a scattering of 0.3% or less measured at the 4.7° (degree) angle.

According to another aspect of the present disclosure, the zirconium-coated nanotube film has a scattering of 0.2% or less measured at the 4.7° (degree) angle.

### BRIEF DESCRIPTION OF THE DRAWINGS

The present disclosure is further described in the detailed description which follows, in reference to the noted plurality of drawings, by way of non-limiting examples of preferred embodiments of the present disclosure, in which like characters represent like elements throughout the several views of the drawings.

FIG. 1 illustrates a flow chart of producing a Zirconium (Zr)-coated-pellicle film in accordance with an exemplary embodiment.

FIG. 2 illustrates correlations between average areal densities and visible light transmission rates in accordance with an exemplary embodiment.

### DETAILED DESCRIPTION

Through one or more of its various aspects, embodiments and/or specific features, sub-components, or processes of the present disclosure, are intended to bring out one or more of the advantages as specifically described above and noted below.

All numbers expressing quantities of ingredients, reaction conditions, thicknesses, and so forth used in the specification and claims may optionally be understood as being modified in all instances by the term “about.” Accordingly, the numerical parameters set forth in the following specification and attached claims may be approximations that may vary depending upon the desired properties sought to be obtained by the present invention. At the very least, and not as an attempt to limit the application of the doctrine of equivalents to the scope of the claims, each numerical parameter should be construed in light of the number of significant digits and ordinary rounding approaches.

Notwithstanding that the numerical ranges and parameters setting forth the broad scope of the invention may be approximations, the numerical values set forth in the specific examples are reported as precisely as possible. Any numerical value, however, inherently contains certain errors necessarily resulting from the standard deviation found in their respective testing measurements. Every numerical range given throughout this specification will include every narrower numerical range that falls within such broader numerical range, as if such narrower numerical ranges were all expressly written herein.

A pellicle may refer to a thin transparent membrane that protects a photomask during semiconductor microchip production. The pellicle construes a protective device with a border frame and a central aperture. Both border and aperture are covered by a continuous thin film on their top of at least a portion of the border and the entire aperture. The center portion of such a thin film over the aperture is free-standing. The pellicle may act as a dust cover that prevents particles and contaminants from falling onto the photomask during production. However, the pellicle must be sufficiently transparent to allow transmission of light and, more importantly, EUV irradiation for performing lithography. A higher level of light transmission is desired for more effective EUV photolithography.

Also, when EUV light travels in a vacuum or an EUV scanner chamber filled with hydrogen gas through a pellicle and then returns to the vacuum or hydrogen environment, a portion of the light is absorbed by the pellicle, followed by radiation in a deviated direction, called scattering. This EUV scattering may cause aberrant light patterns on the masks and, ultimately, on the silicon wafters, causing printing errors, resolution reduction, and/or lower production yields. The total amount of scattered light that deviates from its original path within a 4.7-degree angle is measured, and the result becomes a critical parameter of the current industry standard, scattering.

Further, pellicles for EUV lithography require a long lifetime to support continuous manufacturing operation and avoid frequent pellicle replacement and production interruption due to the pump-down and venting cycles of EUV scanners. One of the suggested resolutions is to apply a thin metallic coating on the pellicle film. When the EUV irradiation is off or during an interval between two EUV irradiations, this metallic coating releases the absorbed heat gained during the EUV irradiations. It increases the emissivity of the pellicle film, thus reducing the pellicle film temperature and extending the pellicle film lifetime.

Any selected coating material must retain the high EUV transmission rate with very mild transmittance reduction. Further EUV transmittance reduction may be unacceptable due to the high-transmission requirement of EUV photolithography. Secondly, the metallic coating should not alter the scattering pattern meaningfully to contravene the stringent scattering standard. The coating material must be “transferred” onto the surface of the pellicle film, bond to the surface, and sustain a high-temperature environment without any peeling-off effect during the EUV irradiation, which results in contamination of the reticle, mask, or scanner chamber.

In this aspect, carbon nanotubes have been suggested as a possible starting material to create pellicles for this EUV pellicle application, together with a metal coating, as one of the approaches to produce, use, and prolong the use of pellicle film under the EUV irradiation.

### Carbon Nanotubes and Carbon Nanotube Films

Carbon nanotubes (CNTs) generally have several different types, including, without limitation, single-walled CNTs (SWCNTs), double-walled CNTs (DWCNTs), multi-walled CNTs (MWCNTs) and coaxial nanotubes. They may exist substantially pure in one type or often in combination with other types. An individual CNT may be intersected with a few others. Together, many CNTs could form a mesh-like free-standing microstructure thin film. As the name suggests, SWCNTs have one or single wall, DWCNTs have two walls, and MWCNTs have three or more walls.

Further, among several possible methods to fabricate free-standing films, a filtration-based approach was utilized to produce films from small-size films to sufficiently large and uniform films for EUV lithography. This filtration-based method allows for quick manufacturing of films not only of CNTs but also other high aspect ratio nanoparticles and nanofibers such as boron nitride nanotubes (BNNT) or silver nanowires (AgNW). Since this approach separates the nanoparticles synthesis method and the film manufacturing method, a variety of types of nanotubes produced by virtually any method may be used. Different types of nanotubes can be mixed in any desired ratio, such as a mixture of two or more CNTS selected from SWCNT, DWCNTs, and MWCNTs. As filtration is a self-leveling process in the sense that non-uniformities of film thickness during the filtration process are self-corrected by the variations of local permeability and, therefore, a highly desirable film formation process, it is also a promising candidate for the production of highly uniform films.

After a successful filtration process, a filter film is formed and harvested for Zr coating by electron-bean or other physical vapor deposition methods.

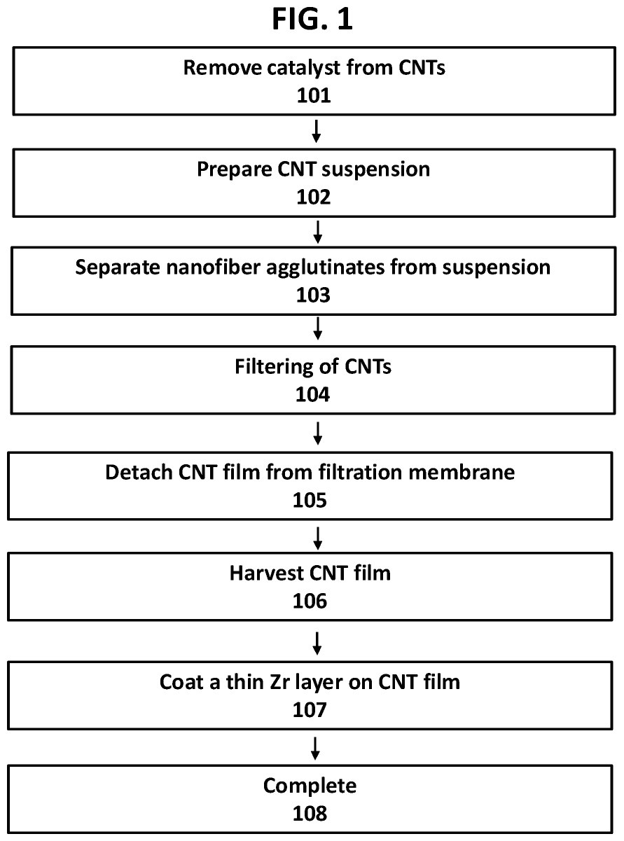

FIG. 1 illustrates a flow chart for producing a Zr-coated-pellicle film in accordance with an exemplary embodiment.

As illustrated in FIG. 1, a free-standing carbon nanotube-based pellicle film may be produced via a filtration-based method. In operation 101, a catalyst is removed from carbon nanotubes (CNTs) that are to be used to form a water-based suspension. In an example, prior to dispersion into a suspension, the CNTs may be chemically purified to reduce a concentration of catalyst particles to less than 1% or preferably less than 0.5% wt. as measured by thermogravimetric analysis. Removal of the catalyst is not limited to any particular process or procedure, such that any suitable process may be utilized to achieve a desirable result.

In operation 102, a water-based suspension is prepared using the purified CNTs, such that the purified CNTs are evenly dispersed in water. When preparing one or more CNT suspensions, carbon nanotube material may be mixed with a selected solvent to uniformly distribute nanotubes in a final solution as a suspension. Mixing can include mechanical mixing (e.g., using a magnetic stir bar and stirring plate), ultrasonic agitation (e.g., using an immersion ultrasonic probe), or other methods. In some examples, the solvent can be a protic or aprotic polar solvent, such as water, isopropyl alcohol (IPA), and aqueous alcohol mixtures, e.g., 60, 70, 80, 90, 95% IPA, N-Methyl-2-pyrrolidone (NMP), dimethyl sulfide (DMS), and combinations thereof. In an example, a surfactant may also be included to aid the uniform dispersion of carbon nanofibers in the solvent. Examples of surfactants include, but are not limited to, anionic surfactants.

Carbon nanofiber films are generally formed from one of MWCNTs, DWCNTs, or SWCNTs. A carbon nanofiber film may also include a mixture of two or more types of CNTs (i.e., SWCNTs, DWCNTs, and/or MWCNTs) with a variable ratio between the different types of CNTs.

Each of these three different types of carbon nanotubes (MWCNT, DWCNT, and SWCNT) has different properties. In one example, single wall carbon nanotubes can be more conveniently dispersed in water or water with a solvent (i.e., with the majority of nanotubes suspended individually and not adsorbed onto other nanotubes) for subsequent formation into a sheet of randomly oriented carbon nanotubes. This ability of individual nanotubes to be uniformly dispersed in water or water with a solvent can, in turn, produce a more planarly uniform nanotube film formed by removing the water and solvent from the nanofiber suspension. This physical uniformity can also improve the uniformity of the properties across the film (e.g., even irradiation transmission across a film).

As used herein, the term “nanofiber” means a fiber having a diameter less than 1 μm. As used herein, the terms “nanofiber” and “nanotube” are used interchangeably and encompass both single wall carbon nanotubes, double wall carbon nanotubes and/or multiwall carbon nanotubes in which carbon atoms are linked together to form a cylindrical structure.

In an example, the initially formed water-based CNT suspension in operation 102 may have at least above 85% purity of SWCNTs. The remaining may be a mixture of DWCNTs, MWCNTs and/or a catalyst. In other examples, a dispersed CNT suspension with various ratios of different types of CNTs may be prepared, such as about 20%/75% DWCNTs/SWCNTs, about 50%/45% DWCNTs/SWCNTs, about 70%/20% DWCNTs/SWCNTs, with MWCNTs accounted for the remaining. In an example, anionic surfactants may be utilized as the catalyst in the suspension.

In operation 103, the CNT suspension is then further purified to remove the aggregated or agglutinated CNTs from the initial mixture. In an example, different forms of CNTs, undispersed or aggregated vs. fully dispersed, may be separated from the suspension via centrifugation. Centrifugation of surfactant-suspended carbon nanotubes may aid in decreasing the turbidity of the suspension solution and ensuring a full dispersion of the carbon nanotubes in the final suspension solution before going into the next filtration step. However, aspects of the disclosure are not limited thereto, such that other separation methods or processes may be utilized.

In operation 104, the CNT supernatant from operation 103 is then filtered through a filtration membrane to form a CNT web, a continuous sheet of film of intersecting CNTs.

In an example, one technique for making the CNT film uses water or other fluids to deposit nanotubes in a random pattern on a filter. The evenly dispersed CNT-containing mixture is allowed to pass through or is forced to pass through the filter, leaving nanotubes on the surface of the filter to form a nanotube structure or a film. The size and shape of the resulting film are determined by the size and shape of the desired filtration area of the filter, while the thickness and density of the membrane are determined by the quantity of nanotube material utilized during the process and the permeability of the filtration membrane to the ingredients of the input CNT material, as the impermeable ingredient is captured on the surface of the filter. If the concentration of nanotubes dispersed in the fluid is known, the mass of nanotubes deposited onto the filter can be determined from the amount of fluid that passes through the filter and the resulting film's average areal density is determined by the nanotube mass divided by the total filtration surface area. The selected filter is generally not permeable to any CNTs in accordance with the embodiments of this disclosure.

The filtration formed CNT film may be of a combination of SWCNT, DWCNT, and/or MWCNT in differing compositions.

In operation 105, the CNT film is then detached from the filtration membrane. More specifically, carbon nanofibers may become intersected randomly to form an interconnected network structure in a planar orientation to form the thin CNT film.

In operation 106, the lifted CNT film is then harvested using a harvester frame and then directly transferred and mounted onto virtually any solid substrate, such as a metal frame, a silicon frame, or a pellicle border with a defined aperture. The CNT film may be mounted to the pellicle border and cover the aperture to form a pellicle. The transferred film mounted on a metal frame or silicon frame with a central opening of as small as 1 cm×1 cm may be useful. A much larger film is in high demand for an actual EUV pellicle. Exemplary embodiment of the present disclosure covers a filtered CNT pellicle film having a different constitution from known prior art while exhibiting properties meeting or exceeding certain aspects of EUV lithography requirements, including, but not limited to, EUV transmittance (EUVT), low scattering, and lifetime test.

This constitution of the pellicle film provides an ultra-thin pellicle film, which allows for very high EUVT (e.g., greater than 88%, 92%, or 95%) while being extremely temperature resistant (e.g., resistant to temperatures above 450° C.) and mechanically robust. In an example, a minimum EUVT may be a value of 88% or greater. Although the above-noted disclosure was provided with respect to CNTs and water solution, aspects of the present disclosure are not limited thereto, such that different nanotubes, such as boron nitride nanotubes (BNNT), may be utilized by the same principle.

The above-mentioned thin films may also be conformally coated by various methods, including, without limitation, E-beam, chemical vapor deposition, atomic layer deposition, spin coating, dip coating, spray coating, sputtering, DC sputtering, and RF sputtering. The material may be a metal element including any one of the following, silicon, SiO₂, SiON, boron, ruthenium, boron, zirconium, niobium, molybdenum, rubidium, yttrium, YN, Y₂O₃, strontium, and/or rhodium. The material may also be any one of a metal, metal oxides or nitrides. However, aspects of the present disclosure are not limited thereto, such that a combination of materials may be used in the coating.

According to exemplary aspects of the present disclosure, the above-mentioned thin films, such as nanotube films, may be coated with the zirconium layer that is about 1.5 nm thick or less on one side or both sides of the nanotube films.

However, aspects of the present disclosure are not limited thereto, such that the zirconium-coated layer may be 1.5 nm thick on a single side or 1 nm thick or less, or 0.3 nm on each side of the nanotube films.

### Electron-Beam Evaporation Coating

An electron-beam (E-beam) evaporation is a physical vapor deposition technique to evaporate a source material using high-energy electrons in the form of an intense beam. The E-beam machine causes the thermionic emission of electrons, which can, after acceleration, provide sufficient energy for evaporating any material, in this instance, yttrium, ruthenium, or zirconium metals. At the beginning of the process, a metal element sample is mounted on a rotating planetary fixture. The fixture is loaded onto a carrier in the E-beam chamber. A crucible(s), a container withholding a material to be evaporated for coating, is placed into its holder. The holder's shutter is closed and then the E-beam chamber is closed.

The chamber is pumped down to 5×10⁻⁶ Torr or below. The selected film thickness is then entered into the device. The power supply is provided to the E-beam gun to create the electron current aiming at the material inside the crucible. The current is then increased until the material starts to melt. For a deposition process, a specific current commonly applied for each selected metallic element as different metallic material often has different melting temperature, for example, Yttrium or zirconium.

Then, the planetary carrier is rotated, the crucible shutter is opened, and the current is increased further to initiate the deposition after the material is molten. The E-beam machine is typically equipped with a deposition thickness monitor.

When the monitored thickness reaches a preselected target value, the shutter is closed, and the current is reduced to zero, and the system is allowed to cool off before venting the chamber.

A coating thickness may be monitored by the amount of a metal element deposited on a target surface. An amount of an element laid on a coating area determines a coating areal density. When a pre-determined coating areal density is reached, the coating process will stop, and the coating is completed.

### Magnetron Sputtering Coating

The magnetron sputtering offers the capability of depositing a dense and defect-free coating of desired material at high deposition rates. It starts with placing a selected coating material on a magnetron inside a vacuum chamber, which may be niobium. The magnetron is an electron tube for amplifying or generating microwaves with electrons controlled by an external magnetic field. Fill the chamber with an inert gas. Apply a negative charge to the magnetron, eventually causing the release of targeted Nb molecules. These target molecules are then collected at the substrate, e.g., the CNT film.

Methods of surface coatings also refer to surface depositions herein, however, aspects of the present disclosure are not limited to the list above. Implementation of the current invention is not limited to E-beam and magnetron sputtering of physical vapor deposition (PVD). Other PVD methods include, but are not limited to, thermal evaporation, remote plasma sputtering, electrochemical deposition, and electroplating. Additionally, atomic layer deposition and chemical vapor deposition may be applicable to achieve a thin-layer coating or deposition over the nanotube surfaces.

### Thin Film Thickness

An exemplary embodiment of the present disclosure is further analyzed for its thickness which is critical to determine and ensure a high EUVT. More specifically, a Dimension Icon AFM instrument was calibrated first against a National Institute of Standards and Technology (NIST) traceable standard. An area of approximately 90 μm×90 μm of CNT pellicle film was selected for AFM 2D and 3D height imaging. Step height analyses were performed to measure the film thickness. Three measurements from three carbon nanotube film samples were taken with readings of 11.8 nm, 10.6 nm, and 11.4 nm, respectively. The average thickness of the testing subject was about 11.3±0.6 nm.

Further, based on additional measurement sets, thickness values ranging from 3 nm to 100 nm, from 3 nm to 40 nm, and from 3 nm to 20 nm were provided.

In addition, thickness values may also range from 3 nm to 100 nm, from 3 nm to 40 nm, and from 3 nm to 20 nm in other samples. However, aspects of the present application are not limited thereto, such that a range may have a lower-end value of 3 nm to 5 nm and an upper-end value of 20 nm to 100 nm.

Given the much higher mechanical strength exhibited by the DWCNT dominant CNT pellicle film, the DWCNT dominant CNT pellicle film may be structured to be extremely thin to allow for higher EUVT values without sacrificing mechanical strength or integrity for use in an EUV scanner. A thinner film may absorb and hold less heat by itself and may also provide a better lifetime.

### Visible Light and EUV Transmittance

Various properties of Zr-coated-CNT pellicle films were measured.

Visible light transmittance at 550 nm was collected for each tested Zr-coated pellicle film with a 1 mm diameter light beam. Each sample test took multiple reads, and an average value was recorded.

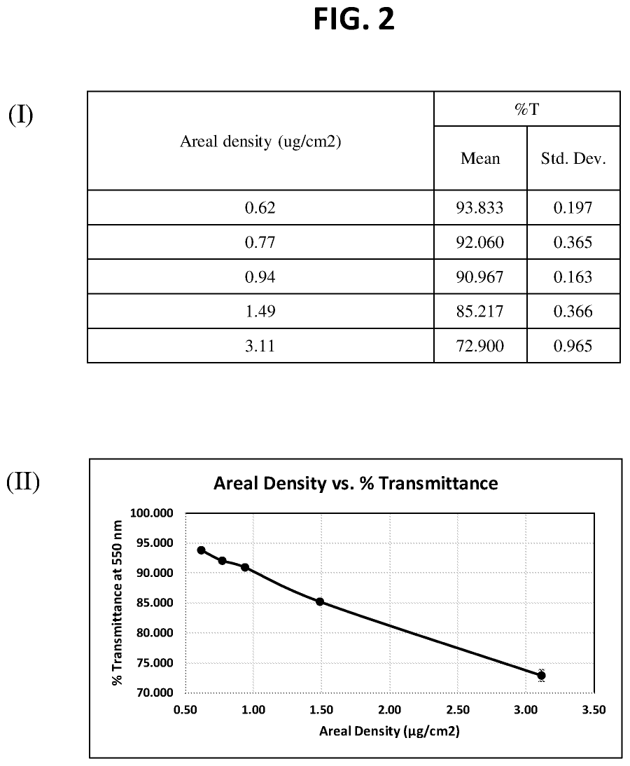

FIG. 2 illustrates correlations between nanotube film areal densities and the film's optical transmittances at a visible light wavelength of 550 nm. From both the table and chart of FIG. 2, it can be seen that when the areal density gets higher, the visible light transmittance goes lower in a strong linear correlation. The actual value of a visible light transmittance may change when the average length, average diameter, and nanotube types for suspension preparation varies. The visible light transmittance has a better and stronger linear correlation with the EUV transmittance.

The EUV transmittance of the sample was measured with the current industry standard of 13.5 nm wavelength. A 110×140 mm full-size pellicle for EUV lithography may require a minimum of 4 measurements and up to 99 measurements or more to determine an average of EUVT and EUVT variations. For an accurate EUV transmittance map, more measurements are preferred, such as 100 measurements. An EUV light beam may have a spot size and shape of less than 2 mm diameter or a rectangular shape of 1 mm×2 mm².

An EUVT map was created based on the EUV scanning results to demonstrate and measure variation and/or uniformity of the transmittance.

The EUV pellicle lifetime tests were conducted under high-intensity EUV irradiation for the coated and control samples. EUV irradiation was performed with an irradiation intensity of 13.4 W/cm², 2.5 hours, equivalent to the intensity on an EUV mask with a 600 W light source, with 20 Pa of hydrogen gas. This is approximately equivalent to the processing of 13,000 wafers, which may equate to a total EUV irradiation energy of 120 KJ/cm².

Different or higher EUV energies may be further applied in other lifetime studies, resembling higher wafer number exposures in production processes.

Also, the surface structure roughness of pellicle films may be important for EUV photolithography performance and product yields. A rough surface modifies the diffraction intensities used for structure reconstruction based on a rigorous calculation of EUV diffraction. In some embodiments, a roughened reflective surface may be configured in a way such that an angular scattering profile meets the EUV lithography requirement. One of the stringent and critical thresholds of EUV lithography for ensuring the ultimate accurate manufacture and printing results is a scattering of less than 0.2% at the 4.7-degree angle according to the current industry standard. A scattering less than 0.5% may be acceptable when other accommodative measures are taken into consideration.

At least one embodiment of the present disclosure was tested by EUV reflectometry for scattering tests and results.

### Coated Pellicle Films

The constitution of the present pellicle films provides an ultra-thin pellicle film, which allows for very high EUVT (e.g., greater than 92% or 95%) while being extremely temperature resistant (e.g., resistant to temperatures above 600° C.) and mechanically robust. The filtration-formed CNT pellicle films may have different optical transmission rates, which can range from 50% to 95% at 550 nm, depending upon the total amount of input nanotube material. Pellicle films with high optical transmission rates may exhibit a very high EUV transmission rate, generally above 88%, with results above 92% or beyond 95 or 98% in some instances. Both visible light transmittance and EUV transmittance may correlate well with each other. One transmittance value, either at visible light wavelength or EUV wavelength, may be extrapolated from the measurement results of another transmittance value based on the correlations. In another example, an across sample scan of a full-size pellicle film (about 110 mm×144 mm or larger) demonstrates an average 96.69±0.15% transmission rate, while scanning the 1.5 mm×1.5 mm center region yields an average 96.75±0.03% transmission rate. A more stringent criterion to evaluate EUVT uniformity is used to calculate the difference between any two EUVT measurements from the same nanotube film in any focused area. This requirement may be less than 5%, less than 2%, or even less than 1.0% or lower. For a full-size pellicle of this exemplary embodiment, the multipoint EUVT uniformity test results (e.g, 100-point measurement per sample) demonstrate some tiny variation of less than 1.5%, less than 0.9%, 0.6%, or less than 0.4%.

Nanotube pellicle films were coated with selected metal elements and tested with results shown in Tables 1, 2, and 3.

TABLE 1

| | | | Tₐᵥₑ | EUVT (%) | | Scattering |
|---|---|---|---|---|---|---|
| Coating | Film | Coating | (%) @ | Across the Sample | | (%) at 4.7 |
| Element | No. | Thickness | 550 nm | Average | SD | degree |
| Ru | — | 2.5 nm | 73.8 | 92.72 | 0.1 | 0.42 |
| Zr | Zr-1 | 1.0 nm/ | 89.5 | 88.63 | 0.13 | 0.42 |
| | | 1.0 nmm | | | | |
| Zr | Zr-2 | 0.5 nm/ | 89.4 | 92.39 | 0.12 | 0.29 |
| | | 0.5 nm | | | | |
| Y | — | 1.0 nm/ | 89.8 | 90.64 | 0.12 | 0.55 |
| | | 1.0 nm | | | | |
| Uncoated | UC-1 | n/a | 90.4 | 96.69 | 0.11 | 0.15 |

According to exemplary aspects of the present disclosure, a first Zr-coated pellicle (Zr-1) as provided in Table 1 had a 1.0 nm-thick layer of Zr deposited first on one side of the CNT film by the E-beam method. The nanotube film was turned 180 degrees for deposition of the same material by the same process on the opposite side.

According to another exemplary aspect of the present disclosure, a second Zr-coated pellicle (Zr-2) as provided in Table 1 had a 0.5 nm-thick layer of Zr deposited first, followed by another 0.5 nm-thick layer of Zr deposited on the opposite side of the nanotube film by the same E-beam deposition methodology.

According to one of the exemplary aspects of the present disclosure, a yttrium-coated pellicle as provided in Table 1 has a 1.0 nm-thick layer of Y deposited first on one side of the CNT film, followed by another 1.0 nm-thick layer of Y deposition on the opposite side of the same membrane by E-beam.

According to exemplary aspects of the present disclosure, a ruthenium-coated pellicle as provided in Table 1 has a 1.5 nm-thick layer of Ru deposited on one side of the pellicle film by magnetron sputtering.

According to exemplary aspects of the present disclosure, an uncoated or pristine nanotube pellicle (UC-1) as provided in Table 1 has an average visible light transmittance of 90.4% and a measured EUVT of about 96.7%.

All pellicle films of the Zr-1, Zr-2, Y-coating, Ru-coating, and UC-1 were produced from the same batch of pristine samples with about the same area density. The test results, as shown in Table 1, demonstrate at least one exemplary embodiment of the present disclosure. The Ru-coated film significantly reduced the visible light transmittance. Ru-coated and Yttrium-coated nanotube films have a scattering test result of greater than 0.4% at the 4.7-degree angle. Together with unstable lifetime test results (i.e., films break during the lifetime tests), Ru-coating and Yttrium coating of nanotube pellicles do not meet the EUV requirements compared to uncoated or Zr-coated nanotube films.

Further investigation of Zr coatings was performed, and the test results are given below and summarized in Tables 2 and 3.

TABLE 2

| | | | Tₐᵥₑ | EUVT (%) | | Scattering |
|---|---|---|---|---|---|---|
| Coating | Film | Coating | (%) @ | Across the Sample | | (%) 4.7 |
| Element | No. | Thickness | 550 nm | Average | SD | degree |
| Uncoated | UC-2 | n/a | 90.3 | 96.86 | 0.18 | 0.07 |
| Uncoated | UC-3 | n/a | 93.1 | 97.75 | 0.16 | 0.12 |
| Zr | Zr-3 | 1.6 nm | 89.96 | 94.34 | 0.09 | 0.107 |
| Zr | Zr-4 | 0.3 nm/ | 80.06 | 88.62 | 0.11 | 0.078 |
| | | 0.3 nm | | | | |
| Zr | Zr-5 | 0.3 nm/ | 90.0 | 94.04 | 0.18 | 0.16 |
| | | 0.3 nm | | | | |
| Zr | Zr-6 | 0.3 nm/ | 93.0 | 95.29 | 0.14 | 0.07 |
| | | 0.3 nm | | | | |

According to one exemplary aspect of the present disclosure, a third Zr-coated pellicle (Zr-3) has an average 1.6 nm-thick layer of Zr deposited only on one side of the CNT film. In an example, the Zr coating may be performed using the magnetron sputtering protocol. Further Zr-3 was measured to have an average visible light transmission rate of about 90.0%. The film may be further coated on the other side by magnetron sputtering protocol.

According to another exemplary aspect of the present disclosure, a fourth Zr-coated pellicle (Zr-4) has a 0.3 nm-thick layer of Zr deposited first on one side of the CNT film, followed by another 0.3 nm-thick layer of Zr deposited on the opposite side of the same film via the E-beam methodology. The Zr-4 has a visible light transmission rate about 80.06%.

According to yet another exemplary aspect of the present disclosure, a fifth Zr-coated pellicle (Zr-5) has a 0.3 nm-thick layer of Zr deposited first on one side of the CNT film, followed by another 0.3 nm-thick layer of Zr deposited on the opposite side of the same membrane via the same E-beam methodology. The Zr-5 has a visible light transmission rate about 90.0%.

According to yet another exemplary aspect of the present disclosure, a sixth Zr-coated pellicle (Zr-6) has a 0.3 nm-thick layer of Zr deposited first on one side of the CNT film, followed by another 0.3 nm-thick layer of Zr deposited on the opposite side of the same film via the same E-beam methodology. The Zr-6 has a visible light transmission rate about 93.0%.

TABLE 3

| | | Coating | Tₐᵥₑ (%) | EUVT (%) | | 13K | Scattering |
|---|---|---|---|---|---|---|---|
| Coating | Film | Areal | @ 550 | Across the Sample | | lifetime | (%) 4.7 |
| Element | No. | Density | nm | Average | SD | test | degree |
| Zr | Zr-7 | 0.19 | 90.44 | 93.5 | 0.10 | | 0.164 |
| | | μg/cm²/ | | | | | |
| | | 0.19 | | | | | |
| | | μg/cm² | | | | | |
| Zr | Zr-8 | 0.19 | 93.24 | 94.95 | 0.08 | Survived | 0.123 |
| | | μg/cm² / | | | | | |
| | | 0.19 | | | | | |
| | | μg/cm² | | | | | |

According to one exemplary aspect of the present disclosure, a seventh Zr-coated pellicle (Zr-7) has a coating areal density of 0.19 microgram/cm² of Zr deposited first on one side of the CNT film, followed by another Zr coating with an areal density of 0.19 microgram/cm² deposited on the opposite side of the same film by E-beam. The Zr-7 has an average visible light transmission rate of about 90.4%,

According to another exemplary aspect of the present disclosure, an eighth Zr-coated pellicle (Zr-8) has an areal density of 0.19 microgram/cm² of Zr deposited first on one side of the CNT film, followed by another Zr-coating with an areal density of 0.19 microgram/cm² deposited on the opposite side of the same film by E-beam. The Zr-8 has an average visible light transmission rate of about 93.0%.

All coatings of any of the exemplary embodiments noted above, including Zr-1 to Zr-8 pellicle films, have a thickness of less than 2 nanometers, and Zr-4 to Zr-6 film coatings are within sub-nanometer ranges. According to exemplary aspects, each layer by itself may not cover every possible area or spot on a surface. According to one embodiment of the present disclosure, a coating thickness or coating areal density may be an average value considering the processes themselves, possible process defects, and technical challenges and difficulties.

As shown in Table 2, pristine nanotube pellicles having an average visible light transmittance of 90.3% (UC-2) and 93.1% (UC-3) have measured EUVT of about 96.9% and 98.0%, respectively.

According to yet another aspect of the present disclosure, the coated nanotube pellicle films generally have a high EUV transmittance of 88% or above for Zr-4 to Zr-8. Pellicle films Zr-5 to Zr-8 have EUVT at 93% or above, with Zr-6 EUVT surpassing 95%.

According to yet another aspect of the present disclosure, all pellicle films listed in Tables 2 and 3 survive a lifetime test equivalent to at least 10,000 wafers at 600-watt irradiation power with the presence of hydrogen gas (i.e., total EUV irradiation energy at least 100 KJ/cm²) without any breakage.

At the time of filing this application, high-resolution EUV photolithography of under 0.7 nm is still under development. The actual lifetime test parameters for industry standards have not reached a consensus. A high wafer number equivalent test above 100 kJ/cm² may still be possible, which surpasses the 10,000-wafer equivalent test detailed herein. In at least one study, the uncoated nanotube film, according to one aspect of the current disclosure, broke in a 32,000 wafer-equivalent lifetime test (total EUV irradiation energy 288 kJ/cm²), while a thin Zr-coated ultra-thin nanotube film, 1.0 nm-thick coating on each side of the film, survived and remained intact.

As illustrated, Zu-coating of ultra-thin nanotube pellicles and pellicle films in accordance with the exemplary embodiments of the present application construes an ultra-thin nanotube-based EUV pellicle with Zr coating at an average thickness of 0.3 nm.

Table 2 exemplarily represents the data from the nanotube pellicles that survive a lifetime test equivalent to 10,000 wafers at 600-watt irradiation power with the presence of hydrogen gas (total EUV irradiation energy 100 KJ/cm²). They have low EUV scattering results, less than 0.2% measured at a 4.7-degree angle, and different film densities, ranging from about 80% to 93% of visible light transmittance at 550 nm.

Table 3 exemplarily represents the data from the nanotube pellicles that survive a lifetime test with a total EUV irradiation energy of 100 KJ/cm² with a less than 0.2% scattering measured at a 4.7-degree angle and film densities from about 90% to 93% of visible light transmittance at 550 nm.

The illustrations of the embodiments described herein are intended to provide a general understanding of the various embodiments. The illustrations are not intended to serve as a complete description of all of the elements and features of products and methods that form the products or methods described herein. Many other embodiments may be apparent to those of skill in the art upon reviewing the disclosure. Other embodiments may be utilized and derived from the disclosure, such that structural and logical substitutions and changes may be made without departing from the scope of the disclosure. Additionally, the illustrations are merely representational and may not be drawn to scale. Certain proportions within the illustrations may be exaggerated, while other proportions may be minimized. Accordingly, the disclosure and the figures are to be regarded as illustrative rather than restrictive.

One or more embodiments of the disclosure may be referred to herein, individually and/or collectively, by the term “invention” merely for convenience and without intending to voluntarily limit the scope of this application to any particular invention or inventive concept. Moreover, although specific embodiments have been illustrated and described herein, it should be appreciated that any subsequent arrangement designed to achieve the same or similar purpose may be substituted for the specific embodiments shown. This disclosure is intended to cover any and all subsequent adaptations or variations of various embodiments. Combinations of the above embodiments, and other embodiments not specifically described herein, will be apparent to those of skill in the art upon reviewing the description.

The Abstract of the Disclosure is submitted with the understanding that it will not be used to interpret or limit the scope or meaning of the claims. In addition, in the foregoing Detailed Description, various features may be grouped together or described in a single embodiment for the purpose of streamlining the disclosure. This disclosure is not to be interpreted as reflecting an intention that the claimed embodiments require more features than are expressly recited in each claim. Rather, as the following claims reflect, inventive subject matter may be directed to less than all of the features of any of the disclosed embodiments. Thus, the following claims are incorporated into the Detailed Description, with each claim standing on its own as defining separately claimed subject matter.

The above disclosed subject matter is to be considered illustrative, and not restrictive, and the appended claims are intended to cover all such modifications, enhancements, and other embodiments which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

What is claimed is:

1. An extreme ultraviolet (EUV) photolithography nanotube film comprising:
a plurality of nanotubes that are intersected randomly to form an interconnected network structure in a planar orientation, the interconnected network structure having a thickness ranging from a lower limit of 3 nm to an upper limit of 100 nm and a zirconium-coated layer.

2. The EUV photolithography nanotube film according to claim 1, wherein the zirconium-coated layer is 1.6 nm thick or less on at least one side of the nanotube film.

3. The EUV photolithography nanotube film according to claim 1, wherein the zirconium-coated layer has an average thickness between 0.5 nm and 1.0 nm.

4. The EUV photolithography nanotube film according to claim 1, wherein the zirconium-coated layer has an average thickness between 0.3 nm and 0.5 nm.

5. The EUV photolithography nanotube film according to claim 1, wherein an average thickness of the zirconium-coated layer is 0.3 nm.

6. The EUV photolithography nanotube film according to claim 1, wherein an areal density of the zirconium-coated layer is 0.19 microgram/cm² on each side of the nanotube film.

7. The EUV photolithography nanotube film according to claim 1, wherein the nanotube film has an EUV scattering of less than 0.5% at 4.7-degree angle.

8. The EUV photolithography nanotube film according to claim 1, wherein the nanotube film has an EUV scattering of less than 0.2% at 4.7-degree angle.

9. The EUV photolithography nanotube film according to claim 1, wherein an average thickness of the interconnected network structure ranges from 11 nm to 40 nm.

10. The EUV photolithography nanotube film according to claim 1, wherein an average thickness of the interconnected network structure is 11 nm.

11. The EUV photolithography nanotube film according to claim 1, wherein the interconnected network structure has a 550 nm light transmittance of at least 80% prior to zirconium coating.

12. The EUV photolithography nanotube film according to claim 1, wherein the interconnected network structure having the zirconium-coated layer has at least 88% EUV transmission rate.

13. The EUV photolithography nanotube film according to claim 1, wherein the interconnected network structure having the zirconium-coated layer has at least 95% EUV transmission rate.

14. The EUV photolithography nanotube film according to claim 1,
wherein the plurality of nanotubes further includes single-walled carbon nanotubes, double-walled carbon nanotubes, and multi-walled carbon nanotubes, and
wherein a number of walls of single-walled carbon nanotubes is one, a number of walls of the double-walled carbon nanotubes is two, and a number of walls of the multi-walled carbon nanotubes is three or more.

15. The EUV photolithography nanotube film according to claim 14, wherein the single-walled carbon nanotubes account for a percentage between 20-40% of all carbon nanotubes, double-walled carbon nanotubes account for a percentage 50% or higher of all carbon nanotubes, the remaining carbon nanotubes are multi-walled carbon nanotubes.

16. The EUV photolithography nanotube film according to claim 1, wherein the interconnected network structure having the zirconium-coated layer remains intact after EUV irradiation in the amount of at least 100 KJ/cm².

17. A method of performing EUV photolithography, comprising transmitting EUV radiation through the EUV photolithograph nanotube of claim 1.
